(19) United States
(12) Patent Application Publication
(10) Pub. No.: US 2021/0115221 A1
(43) Pub. Date: Apr. 22, 2021

(54) COMPOSITION AND SUBSTRATE-TREATING METHOD

(71) Applicant: JSR CORPORATION, Tokyo (JP)

(72) Inventors: Shun Aoki, Tokyo (JP); Takashi Katagiri, Tokyo (JP); Kazunori Takanashi, Tokyo (JP); Motoyuki Shima, Tokyo (JP)

(73) Assignee: JSR CORPORATION, Tokyo (JP)

(21) Appl. No.: 17/134,593

(22) Filed: Dec. 28, 2020

Related U.S. Application Data
(63) Continuation of application No. PCT/JP2019/025256, filed on Jun. 25, 2019.

(30) Foreign Application Priority Data
Jul. 4, 2018 (JP) 2018-127839

(51) Int. Cl. C08K 5/092; C08G 61/10; C08G 61/04; H01L 21/02; B08B 7/00

(52) U.S. Cl. CPC C08K 5/092; C08G 61/10; B08B 7/0014; H01L 21/02057; C08G 61/04

(57) ABSTRACT

A composition enables particles to be removed from a surface of a substrate by: applying the composition on the surface of the substrate to form a substrate treatment film on the surface; and bringing a liquid into contact with the substrate treatment film to remove the substrate treatment film from the surface. The composition includes a resin; and a solvent. The solvent includes a first solvent component having a normal boiling point of no less than 175° C. A content of the first solvent component with respect to 100 parts by mass of the resin is no less than 1 part by mass.

### CROSS-REFERENCE TO RELATED APPLICATIONS

The present application is a continuation application of International Application No. PCT/JP2019/025256, filed Jun. 25, 2019, which claims priority to Japanese Patent Application No. 2018-127839, filed Jul. 4, 2018. The contents of these applications are incorporated herein by reference in their entirety.

### BACKGROUND OF THE INVENTION

### Field of the Invention

The present invention relates to a composition and a substrate-treating method.

### Discussion of the Background

In production processes of semiconductor substrates, cleaning is conducted in order to remove contaminants such as particles attached onto surfaces of substrates having a pattern formed thereon. In recent years, miniaturization of the formed pattern, and/or increase of the aspect ratio have/has advanced. In cleaning through using a liquid and/or gas, it is difficult to achieve the flow of the liquid and/or gas between the pattern walls and/or in the vicinity of a substrate surface, thereby making removal of fine particles and/or the attached particles between the pattern walls difficult.

Japanese Unexamined Patent Application, Publication No. H7-74137 discloses a method in which after feeding a coating liquid on a substrate surface to provide a thin film, particles on the substrate surface are removed by detachment of the thin film with an adhesive tape or the like. According to this method, fine particles and the particles between pattern walls can be reportedly removed at a high removal rate while influences on the semiconductor substrate are decreased.

Japanese Unexamined Patent Application, Publication No. 2014-99583 discloses an apparatus for cleaning a substrate, and a cleaning method for a substrate, in which a treatment liquid for forming a film on a substrate surface is supplied and solidified or hardened, and then the entire treatment liquid solidified or hardened is dissolved in a removing liquid to remove particles on the substrate surface.

However, due to the necessity of physically peeling off the thin film from the surface of the substrate, the methods disclosed in Japanese Unexamined Patent Application, Publication No. H7-74137 could be problematic in terms of complexity of steps, as well as difficulty in removal when a part of the thin film remains in the pattern. Furthermore, although the detailed description of Japanese Unexamined Patent Application, Publication No. 2014-99583 discloses a top coating liquid as a non-limiting example of the treatment liquid, a detailed description as to what kind of treatment liquid is suited is not found.

### SUMMARY OF THE INVENTION

According to an aspect of the present invention, a composition enables particles to be removed from a surface of a substrate by: applying the composition on the surface of the substrate to form a substrate treatment film on the surface; and bringing a liquid into contact with the substrate treatment film to remove the substrate treatment film from the surface. The composition includes a resin; and a solvent. The solvent includes a first solvent component having a normal boiling point of no less than 175° C. A content of the first solvent component with respect to 100 parts by mass of the resin is no less than 1 part by mass.

According to another aspect of the present invention, a substrate-treating method includes: applying a composition on a substrate to form a substrate treatment film on the substrate; and bringing a liquid into contact with a substrate treatment film to remove a substrate treatment film. The composition includes: a resin; and a solvent. The solvent includes a first solvent component having a normal boiling point of no less than 175° C. A content of the first solvent component with respect to 100 parts by mass of the resin is no less than 1 part by mass.

### BRIEF DESCRIPTION OF THE DRAWINGS

FIG. 1A is an explanatory view illustrating an applying step in a substrate-treating method in which the composition for forming a substrate treatment film of an embodiment of the present invention is used;

FIG. 1B is an explanatory view illustrating forming of a substrate treatment film in a substrate-treating method of an embodiment of the present invention; and

FIG. 1C is an explanatory view illustrating a step of bringing a liquid for removing a substrate treatment film into contact in the substrate-treating method of the embodiment of the present invention.

### DESCRIPTION OF EMBODIMENTS

According to an embodiment of the present invention, a composition for forming a substrate treatment film is for use in a substrate-treating method comprising:

applying the composition on the substrate; and

bringing a liquid for removing a substrate treatment film into contact with a substrate treatment film formed by the applying,

wherein the composition comprises:

a resin; and

a solvent,

wherein the solvent comprises a first solvent component having a normal boiling point of no less than 175° C., and

a content of the first solvent component with respect to 100 parts by mass of the resin is no less than 1 part by mass.

According to another embodiment of the present invention, a substrate-treating method comprises:

applying a composition for forming a substrate treatment film on a substrate; and

bringing a liquid for removing a substrate treatment film into contact with a substrate treatment film formed by the applying,

wherein the composition comprises:

a resin; and

a solvent,

wherein the solvent comprises a first solvent component having a normal boiling point of no less than 175° C., and

a content of the first solvent component with respect to 100 parts by mass of the resin is no less than 1 part by mass.

The composition for forming a substrate treatment film and the substrate-treating method of the embodiments of the present invention, for use in a process of removing unwanted substances on the surface of a semiconductor substrate through forming a substrate treatment film on the substrate surface, enable fine particles on the surface of the substrate to be efficiently removed, and enable easy removal of a thus formed substrate treatment film from the surface of the substrate. Therefore, the embodiments of the present invention can be suitably employed in manufacturing processes of semiconductor elements for which further progress of miniaturization, and an increase of the aspect ratio are expected in the future. Hereinafter, the embodiments of the present invention will be described in detail.

### Composition for Forming Substrate Treatment Film

The composition for forming a substrate treatment film is to be used in a substrate-treating method including steps of: applying the composition for forming a substrate treatment film on a substrate; and bringing a liquid for removing a substrate treatment film into contact with a substrate treatment film formed by the applying step. The composition for forming a substrate treatment film contains a resin (hereinafter, may be also referred to as “(A) resin” or “resin (A)”), and a solvent (hereinafter, may be also referred to as “(B) solvent” or “solvent (B)”), in which the solvent (B) includes a first solvent component (hereinafter, may be also referred to as “(B1) solvent component” or “solvent component (B1)”) having a normal boiling point of no less than 175° C., and a content of the solvent component (B1) with respect to 100 parts by mass of the resin (A) is no less than 1 part by mass.

According to the composition for forming a substrate treatment film, by forming a substrate treatment film on the surface of the semiconductor substrate and then removing the substrate treatment film, particles attached to the surface of the semiconductor substrate, particularly a patterned semiconductor substrate, can be efficiently removed (hereinafter, may be also referred to as “particle removability”), and a thus formed substrate treatment film can be easily removed from the surface of the substrate (hereinafter, may be also referred to as “film removability”).

In addition to the resin (A) and the solvent (B), the composition for forming a substrate treatment film may contain, as a favorable component, an organic acid (hereinafter, may be also referred to as “(C) organic acid” or “organic acid (C)”) not being a polymer, and within a range not leading to impairment of the effects of the present invention, may also contain other optional component(s). Each component will be described below.

(A) Resin

The “resin” as referred to means a polymer. The “polymer” as referred to means a compound having at least two structural units. The resin (A) is not particularly limited as long as it is a polymer. The lower limit of a molecular weight of the resin (A) is preferably 300, and more preferably 500. The resin (A) is exemplified by a novolak resin, a resol resin, an aromatic ring-containing vinyl-based resin, an acrylic resin, a calixarene resin, and the like. The resin (A) may be used either alone of one type, or in a combination of two or more types thereof.

Novolak Resin

The novolak resin is a chain polymer obtained by allowing a compound having an aromatic ring to react with an aldehyde compound by using an acidic catalyst.

The compound having an aromatic ring is exemplified by a substituted or unsubstituted aromatic hydrocarbon having 6 to 20 carbon atoms. and the like. Examples of the aromatic hydrocarbon compound having 6 to 20 carbon atoms include benzene, toluene, xylene, phenol, 3-methylphenol, 4-methylphenol, pyrogallol, cresol, naphthalene, α-naphthol, β-naphthol, 1,5-dihydroxynaphthalene, 2,7-dihydroxynaphthalene, anthracene, phenanthrene, tetracene, pyrene, 1-hydroxypyrene, triphenylene, fluorene, 9,9-bis(4-hydroxyphenyl)fluorene, 9,9-bis(6-hydroxynaphthyl)fluorene, indenofluorene, truxene, and the like.

Examples of the aldehyde compound include aldehydes such as formaldehyde, acetaldehyde, propionaldehyde, benzaldehyde and parahydroxybenzaldehyde, and the like. Of these, formaldehyde is preferred. It is to be noted that paraformaldehyde may be used in place of formaldehyde, and paraldehyde may be used in place of acetaldehyde.

The novolak resin preferably has a structural unit (hereinafter, may be also referred to as “structural unit (I)”) represented by the following formula (I).

Structural Unit (I))

The structural unit (I) is represented by the following formula (1).

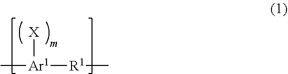

In the above formula (1), Ar¹ represents a group having a valency of (m+2) obtained by eliminating (m+2) hydrogen atoms on the aromatic ring from an arene having 6 to 20 carbon atoms; R¹ represents a substituted or unsubstituted alkylene group having 1 to 20 carbon atoms; X represents a monovalent hetero atom-containing group or a monovalent organic group; and m is an integer of 0 to 10, wherein in a case in which m is no less than 2, a plurality of Xs are identical or different from one another.

Examples of the arene having 6 to 20 carbon atoms that is capable of giving AO include benzene, naphthalene, anthracene, phenanthrene, tetracene, pyrene, triphenylene, fluorene, truxene, and the like. Of these, benzene or naphthalene is preferred, and benzene is more preferred.

The monovalent hetero atom-containing group which may be represented by X is exemplified by a hydroxy group, a halogen atom, and the like. Examples of the halogen atom include a fluorine atom, a chlorine atom, a bromine atom, an iodine atom, and the like. The monovalent hetero atom-containing group which may be represented by X is preferably a hydroxy group.

The “organic group” as referred to herein means a group having at least one carbon atom. The monovalent organic group which may be represented by X is exemplified by: a monovalent hydrocarbon group having 1 to 20 carbon atoms; a group having a divalent hetero atom-containing group between two adjacent carbon atoms of the monovalent hydrocarbon group; a group obtained by substituting with a monovalent hetero atom-containing group, a part or all of hydrogen atoms included in the monovalent hydrocarbon group or the group having a divalent hetero atom-containing group; and the like.

The monovalent hydrocarbon group having 1 to 20 carbon atoms is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

Examples of the monovalent chain hydrocarbon group having 1 to 20 carbon atoms include groups obtained from: alkanes such as methane, ethane, propane and butane; alkenes such as ethene, propene and butene; alkynes such as ethyne, propyne and butyne; and the like by eliminating one hydrogen atom included therein, and the like.

Examples of the monovalent alicyclic hydrocarbon group having 3 to 20 carbon atoms include groups obtained from: alicyclic saturated hydrocarbons, e.g., cycloalkanes such as cyclopentane and cyclohexane, bridged cyclic saturated hydrocarbons such as norbornane, adamantane and tricyclodecane, and the like; alicyclic unsaturated hydrocarbons, e.g., cycloalkenes such as cyclopentene and cyclohexene, bridged cyclic unsaturated hydrocarbons such as norbornene and tricyclodecene, and the like; and the like by eliminating one hydrogen atom included therein.

Examples of the monovalent aromatic hydrocarbon group having 6 to 20 carbon atoms include groups obtained from: arenes such as benzene, toluene, ethylbenzene, xylene, naphthalene, methylnaphthalene, anthracene and methylanthracene by eliminating a hydrogen atom on the aromatic ring or a hydrogen atom on the alkyl group, and the like.

The hetero atom constituting the divalent or monovalent hetero atom-containing group is exemplified by an oxygen atom, a nitrogen atom, a sulfur atom, a phosphorus atom, a silicon atom, a halogen atom, and the like.

Examples of the divalent hetero atom-containing group include —O—, —CO—, —S—, —CS—, —NR′—, groups obtained by combining at least two of the same, and the like, wherein R′ represents a hydrogen atom or a monovalent hydrocarbon group. Of these, —O— and —S— are preferred.

Examples of the monovalent hetero atom-containing group include halogen atoms such as a fluorine atom, a chlorine atom, a bromine atom and an iodine atom, a hydroxy group, a carboxy group, a cyano group, an amino group, a sulfanyl group, and the like.

The monovalent organic group which may be represented by X is preferably an alkyl group or an oxyhydrocarbon group, more preferably an alkyl group or an alkyloxy group, and still more preferably a methyl group, an ethyl group, a propyl group, a butyl group, a methoxy group, an ethoxy group or a propoxy group.

m is an integer that is preferably 1 to 3, more preferably 1 or 2, and still more preferably 1.

It is preferred that in the structural unit (I): m in the formula (1) is an integer of no less than 1; and at least one of X represents a hydroxy group.

Examples of the substituted or unsubstituted alkylene group having 1 to 20 carbon atoms represented by R¹ include a methylene group, a methylmethylene group, a phenylmethylene group, a parahydroxyphenylmethylene group, and the like. Of these, a methylene group or a methylmethylene group is preferred, and a methylene group is more preferred.

Examples of the acidic catalyst include: inorganic acids such as hydrochloric acid, sulfuric acid, and phosphoric acid; organic acids such as methanesulfonic acid, paratoluenesulfonic acid, and oxalic acid; Lewis acids such as boron trifluoride, anhydrous aluminum chloride, and zinc acetate; and the like. Of these, the organic acid is preferred, and paratoluenesulfonic acid is more preferred.

Resol Resin

The resol resin is a polymer obtained by allowing a compound having an aromatic ring to react with an aldehyde compound by using a basic catalyst.

The aldehyde compound and the compound having an aromatic ring are exemplified by compounds similar to the aldehyde compound and the compound having an aromatic ring in connection with the novolak resin, and the like.

Examples of the basic catalyst include: hydroxides of an alkali metal or an alkaline earth metal such as sodium hydroxide, lithium hydroxide, potassium hydroxide, and calcium hydroxide; amine compounds such as ammonia, monoethanolamine, triethylamine, and hexamethylenetetramine; basic substances such as sodium carbonate; and the like.

Aromatic Ring-Containing Vinyl-Based Resin

The aromatic ring-containing vinyl-based resin is a polymer having a structural unit derived from a compound having an aromatic ring and a polymerizable carbon-carbon double bond. Examples of the compound having an aromatic ring and a polymerizable carbon-carbon double bond include styrene, methylstyrene, α-methylstyrene, vinylnaphthalene, phenyl vinyl ether, and the like.

Acrylic Resin

The acrylic resin is a polymer having a structural unit derived from (meth)acrylic acid or a (meth)acrylic acid ester. Examples of the (meth)acrylic acid ester include: alkyl (meth)acrylates such as methyl (meth)acrylate; alicyclic hydrocarbon group esters of (meth)acrylic acid such as cyclohexyl (meth)acrylate; aryl (meth)acrylates such as phenyl (meth)acrylate; fluorine-containing (meth)acrylic acid esters such as 1,1,1,3,3,3-hexafluoro-2-propyl (meth)acrylate and 1,1,1-trifluoro-2-hydroxy-2-trifluoromethyl-4-pentyl (meth)acrylate; and the like.

Calixarene Resin

The calixarene resin is a cyclic oligomer including a plurality of aromatic rings, each having a phenolic hydroxyl group bonded thereto, circularly linked via hydrocarbon groups. Examples of a compound that gives the aromatic ring to which a phenolic hydroxyl group bonds include phenol, methylphenol, t-butylphenol, naphthol, and the like. Examples of the hydrocarbon group include a methylene group, a methylmethylene group, and the like.

The lower limit of a weight average molecular weight (Mw) of the resin (A) is preferably 1,000, more preferably 2,000, still more preferably 3,000, and particularly preferably 5,000. The upper limit of the Mw is preferably 100,000, more preferably 80,000, and still more preferably 60,000.

The Mw as referred to herein is a value determined by gel permeation chromatography (detector: differential refractometer) by using GPC columns available from Tosoh Corporation (“G2000HXL”×2, “G3000HXL”×1 and “G4000HXL”×1) under analytical conditions involving flow rate: 1.0 mL/min, elution solvent: tetrahydrofuran, and column temperature: 40° C., with mono-dispersed polystyrene as a standard.

The lower limit of a proportion of the resin (A) contained with respect to all components other than the solvent (B) of the composition for forming a substrate treatment film is preferably 70% by mass, more preferably 80% by mass, still more preferably 90% by mass, and particularly preferably 95% by mass. The upper limit of the proportion is preferably 99.99% by mass, more preferably 99.9% by mass, and still more preferably 99.0% by mass.

(B) Solvent

The solvent (B) dissolves or disperses the resin (A), and optional component(s) which may be contained as necessary. The solvent (B) contains the solvent component (B1) having a normal boiling point of no less than 175° C. The solvent (B) may further contain a second solvent component (hereinafter, may be also referred to as “(B2) solvent component” or “solvent component (B2)”) having a normal boiling point of no greater than 170° C., in addition to the solvent component (B1), and within a range not leading to impairment of the effects of the present invention, may further contain other solvent component(s) in addition to the solvent component (B1) and the solvent component (B2). Each of the solvent components may be used either alone of one type, or in a combination of two or more types thereof.

The composition for forming a substrate treatment film is superior in film removability and particle removability due to: containing the resin (A) as well as the solvent (B); the solvent (B) containing the solvent component (B1); and the content of the solvent component (B1) with respect to 100 parts by mass of the resin (A) being no less than 1 part by mass. Although not necessarily clarified and without wishing to be bound by any theory, the reason for achieving the effects described above due to the composition for forming a substrate treatment film having such a constitution may be supposed as in the following, for example. Since the composition for forming a substrate treatment film contains, in at least a certain amount, the solvent component (B1) having a comparatively high normal boiling point, it is considered that when the substrate treatment film is formed through evaporation of volatile components in the composition for forming a substrate treatment film applied on the substrate, leading to solidification or hardening of the composition for forming a substrate treatment film on the substrate, a part or all of the solvent component (B1) remains on the substrate treatment film. It is assumed that thus remaining solvent component (B1) facilitates incorporation of particles into the substrate treatment film, thereby improving particle removability and also improving film removability of the substrate treatment film.

(B1) Solvent Component

The solvent component (B1) is a solvent having a normal boiling point of no less than 175° C.

The lower limit of the normal boiling point of the solvent component (B1) is preferably 180° C., more preferably 200° C., still more preferably 215° C., and particularly preferably 230° C. The upper limit of the normal boiling point of the solvent component (B1) is preferably 320° C., more preferably 300° C., still more preferably 290° C., and particularly preferably 280° C. When the normal boiling point of the solvent component (B1) falls within the above range, coating characteristics of the composition for forming a substrate treatment film can be further improved.

The upper limit of C log P of the solvent component (B1) is preferably 0.6, more preferably 0.3, still more preferably 0.0, and particularly preferably −0.25. The lower limit of C log P is preferably −2, more preferably −1.6, still more preferably −1.3, and particularly preferably −1.0. When C log P of the solvent component (B1) falls within the above range, polarity of the solvent component (B1) can be optimized and as a result, the film removability and the particle removability can be further improved.

“C log P” of the solvent component (B1) may be also referred to as “C log Pow,” and means a value of an octanol/water partition coefficient (log P) calculated by a C log P method. A greater value of C log P indicates higher hydrophobicity (lipid solubility). The value of C log P of the solvent component (B1) was determined based on a structural formula of the solvent using “ChemBioDraw Ultra 12.0.2.1076” available from CambridgeSoft Corporation.

“Alcohols” as referred to herein mean solvents each having at least one hydroxy group.

The solvent component (B1) is exemplified by alcohols, ethers and esters, such as compounds presented below, and the like. In the parentheses that follow, each temperature (° C.) indicates the respective value of the normal boiling point, and each numerical value indicates the respective value of C log P.

Examples of the alcohols include:

monohydric alcohols such as benzyl alcohol (205° C., 1.10) and phenylpropanol (236° C., 1.71);

polyhydric alcohols such as ethylene glycol (197° C., 1.37), 1,4-butanediol (230° C., 1.16), 1,3-butanediol (203° C., −0.73), 1,5-pentanediol (240° C., −0.64), 2,5-hexanediol (221° C., −0.55), 1,2-butanediol (193° C., −0.53), 2,2-dimethyl-1,3-propane diol (210° C., −0.24), 2-methyl-2,4-pentanediol (197° C., −0.02), 2,5-dimethyl-2,5-hexanediol (214° C., 0.25), tetraethylene glycol (314° C., −1.58), triethylene glycol (287° C., 1.44), propylene glycol (187° C., 1.06), dipropylene glycol (231° C., −0.69), tripropylene glycol (267° C., −0.29), 1,2-hexanediol (223° C., 0.53), and glycerin (290° C., −1.54);

polyhydric alcohol partial ethers such as ethylene glycol monophenyl ether (237° C., 1.19), diethylene glycol monomethyl ether (193° C., −0.74), diethylene glycol monoethyl ether (196° C., −0.35), triethylene glycol monomethyl ether (248° C., −0.88), dipropylene glycol monomethyl ether (188° C., 0.09), dipropylene glycol monobutyl ether (230° C., 1.54), tripropylene glycol monomethyl ether (243° C., 0.47), diethylene glycol monobutyl ether (230° C., 0.71); and the like.

Examples of ethers include:

polyhydric alcohol whole ethers such as diethylene glycol methyl ethyl ether (176° C., 0.21), diethylene glycol diethyl ether (188° C., 0.60), tetraethylene glycol dimethyl ether (275° C., −0.45), triethylene glycol dimethyl ether (216° C., −0.32), diethylene glycol isopropyl methyl ether (179° C., 0.52), triethylene glycol butyl methyl ether (261° C., 1.13), and diethylene glycol butyl methyl ether (212° C., 1.27); and the like.

Examples of the esters include:

polyhydric alcohol partial ether carboxylates such as diethylene glycol monoethyl ether acetate (219° C., 0.54) and dipropylene glycol monomethyl ether acetate (209° C., 0.77);

polyhydric alcohol whole carboxylates such as 1,3-butylene glycol diacetate (232° C., 1.13);

carbonates such as propylene carbonate (240° C., −0.38); and the like.

As the solvent component (B1), the alcohols are preferred, and solvents each having a plurality of hydroxy groups are more preferred. Additionally/alternatively, as the solvent component (B1), solvents each having an ether bond are preferred. Examples of the solvent having a plurality of hydroxy groups and an ether bond include tetraethylene glycol, triethylene glycol, dipropylene glycol, tripropylene glycol, and the like.

(B2) Solvent Component

The solvent component (B2) is a solvent having a normal boiling point of no greater than 170° C.

Examples of the solvent component (B2) include propylene glycol monomethyl ether acetate (146° C.), ethyl lactate (151° C.), propylene glycol monomethyl ether (121° C.), propylene glycol monoethyl ether (133° C.), propylene glycol monopropyl ether (149° C.), 4-methyl-2-pentanol (132° C.), diethylene glycol dimethyl ether (162° C.), and the like. In the above parentheses, each temperature (° C.) indicates the value of the respective normal boiling point.

Other Solvent Component(s)

Examples of the other solvent component(s) include dipropylene glycol dimethyl ether (171° C.), and the like.

The lower limit of a content of the solvent component (B1) with respect to 100 parts by mass of the resin (A) is typically 1 part by mass, preferably 5 parts by mass, still more preferably 15 parts by mass, even more preferably 50 parts by mass, and particularly preferably 150 parts by mass. The upper limit of the content is preferably 1,000 parts by mass, and more preferably 500 parts by mass.

The lower limit of a proportion of the solvent component (B1) contained in the solvent (B) is preferably 0.01% by mass, more preferably 0.1% by mass, still more preferably 0.5% by mass, particularly preferably 1% by mass, and further particularly preferably 3% by mass. The upper limit of the proportion is preferably 50% by mass, more preferably 30% by mass, and still more preferably 20% by mass. When the proportion of the solvent component (B1) contained falls within the above range, the film removability and the particle removability can be further improved.

(C) Organic Acid

The organic acid (C) is an organic acid not being a polymer. By including the organic acid (C), removal of the film formed on the surface of the substrate is facilitated. The upper limit of the molecular weight of the organic acid (C) is, for example, 500, preferably 400, and more preferably 300. The lower limit of the molecular weight of the organic acid (C) is, for example 50, and preferably 55. The organic acid (C) may be used either alone of one type, or in a combination of two or more types thereof.

As the organic acid (C), carboxylic acids are preferred. Specific examples include:

carboxylic acids constituted of a carboxy group with an aliphatic saturated hydrocarbon group and/or an aromatic hydrocarbon group, such as acetic acid, propionic acid, butanoic acid, pentanoic acid, hexanoic acid, cyclohexanecarboxylic acid, cyclohexyl acetic acid, 1-adamantanecarboxylic acid, benzoic acid and phenylacetic acid;

fluorine atom-containing monocarboxylic acids such as difluoroacetic acid, trifluoroacetic acid, pentafluoropropanoic acid, heptafluorobutanoic acid, fluorophenylacetic acid and difluorobenzoic acid;

monocarboxylic acids including a hetero atom other than a fluorine atom at a part other than the carboxy group, such as 10-hydroxydecanoic acid, 5-oxohexanoic acid, 3-methoxycyclohexanecarboxylic acid, camphorcarboxylic acid, dinitrobenzoic acid, nitrophenylacetic acid, lactic acid, glycolic acid, glyceric acid, salicylic acid, anisic acid, gallic acid and furan carboxylic acid;

monocarboxylic acid compounds, e.g., double bond-containing monocarboxylic acids such as (meth)acrylic acid, crotonic acid, cinnamic acid and sorbic acid;

polycarboxylic acids constituted of a plurality of carboxy groups with a single bond, an aliphatic saturated hydrocarbon group and/or an aromatic hydrocarbon group, such as oxalic acid, malonic acid, succinic acid, glutaric acid, adipic acid, dodecanedicarboxylic acid, propanetricarboxylic acid, butanetetracarboxylic acid, cyclohexanehexacarboxylic acid, 1,4-naphthalenedicarboxylic acid, phthalic acid, isophthalic acid, terephthalic acid, trimellitic acid, pyromellitic acid and 1,2,3,4-cyclobutanetetracarboxylic acid;

partially esterified products of the polycarboxylic acids;

fluorine atom-containing polycarboxylic acids such as difluoromalonic acid, tetrafluorophthalic acid and hexafluoroglutaric acid;

polycarboxylic acids including a hetero atom other than a fluorine atom at a part other than the carboxy group, such as tartaric acid, citric acid, malic acid, tartronic acid, diglycolic acid and iminodiacetic acid;

polycarboxylic acid compounds, e.g., double bond-containing polycarboxylic acids such as maleic acid, fumaric acid and aconitic acid; and the like.

The lower limit of solubility of the organic acid (C) in water at 25° C. is preferably 5% by mass, more preferably 7% by mass, and still more preferably 10% by mass. The upper limit of the solubility is preferably 50% by mass, more preferably 40% by mass, and still more preferably 30% by mass. When the solubility falls within the above range, removal of the film formed can be further facilitated.

It is preferred that the organic acid (C) is in a solid state at 25° C. When the organic acid (C) is in a solid state at 25° C., it is considered that the solid organic acid (C) will be segregated in the film formed from the composition for forming a substrate treatment film, leading to an improvement of removability.

In light of further facilitated removal of the film, the organic acid (C) is preferably the polycarboxylic acid, and more preferably malonic acid, succinic acid, glutaric acid, adipic acid, dodecanedicarboxylic acid, propanetricarboxylic acid, butanetetracarboxylic acid, hexafluoroglutaric acid, cyclohexanehexacarboxylic acid, 1,4-naphthalenedicarboxylic acid, phthalic acid, isophthalic acid, terephthalic acid, trimellitic acid, pyromellitic acid, citric acid, malic acid, aconitic acid or 1,2,3,4-cyclobutanetetracarboxylic acid.

In a case in which the composition for forming a substrate treatment film contains the organic acid (C), the lower limit of a content of the organic acid (C) with respect to 100 parts by mass of the resin (A) is preferably 0.01 parts by mass, more preferably 0.1 parts by mass, still more preferably 0.5 parts by mass, and particularly preferably 1 part by mass. The upper limit of the content is preferably 100 parts by mass, more preferably 50 parts by mass, still more preferably 20 parts by mass, and particularly preferably 10 parts by mass. When the content of the organic acid (C) falls within the above range, the film removability and the particle removability can be further improved.

Other Optional Component(s)

The composition for forming a substrate treatment film may also contain other optional component(s) such as a surfactant. The other optional component may be used either alone of one type, or in a combination of two or more types thereof.

When the composition for forming a substrate treatment film further contains the surfactant, the coating characteristics can be further improved. The surfactant is exemplified by a nonionic surfactant, a cationic surfactant, an anionic surfactant, and the like.

Examples of the nonionic surfactant include ether type nonionic surfactants such as polyoxyethylene alkyl ethers; ether-ester type nonionic surfactants such as polyoxyethylene ethers of a glycerin ester; ester type nonionic surfactants such as polyethylene glycol fatty acid esters, glycerin esters and sorbitan esters; and the like.

The cationic surfactant is exemplified by an aliphatic amine salt, an aliphatic ammonium salt, and the like.

Examples of the anionic surfactant include: carboxylic acid salts such as fatty acid soap and alkyl ether carboxylic acid salts; sulfonic acid salts such as alkylbenzene sulfonic acid salts, alkylnaphthalene sulfonic acid salts and α-olefin sulfonic acid salts; sulfuric acid ester salts such as higher alcohol sulfuric acid ester salts and alkyl ether sulfuric acid salts; phosphoric acid ester salts such as alkyl phosphate esters; and the like.

In the case in which the composition for forming a substrate treatment film contains the surfactant, the upper limit of a content of the surfactant with respect to 100 parts by mass of the resin (A) is for example, 2 parts by mass. The lower limit of the content is, for example, 0.01 parts by mass. When the content of the surfactant falls within the above range, the coating characteristics can be further improved.

Procedure for Preparing Composition for Forming Substrate Treatment Film

The composition for forming a substrate treatment film may be prepared by, for example, mixing the resin (A) and the solvent (B), as well as the optional component(s) such as the organic acid (C) if necessary, at a certain ratio, preferably followed by filtering a resultant mixture through a filter, etc., having a pore size of, for example, 0.1 to 5 The lower limit of a proportion of all components other than the solvent (B) contained in the composition for forming a substrate treatment film is preferably 0.1% by mass, more preferably 0.5% by mass, still more preferably 1% by mass, and particularly preferably 2% by mass. The upper limit of the proportion of all components other than the solvent (B) is typically 20% by mass, more preferably 15% by mass, still more preferably 13% by mass, and particularly preferably 10% by mass. When the proportion of the entire components other than the solvent (B) falls within the above range, the coating characteristics can be further improved.

Substrate-Treating Method

The substrate-treating method includes the steps of: applying the composition for forming a substrate treatment film on a substrate; and bringing a liquid for removing a substrate treatment film into contact with a substrate treatment film formed by the applying step. In the substrate-treating method, the composition for forming a substrate treatment film of the embodiment of the present invention is used as the composition for forming a substrate treatment film.

Due to using the composition for forming a substrate treatment film of the embodiment of the present invention, the substrate-treating method enables, in a process of removing unwanted substances on the surface of a semiconductor substrate through forming a substrate treatment film (hereinafter, may be also referred to as “substrate treatment film (b)”) on the substrate surface, fine particles on the surface of the substrate to be efficiently removed, and also enables easy removal of a thus formed substrate treatment film (b) from the surface of the substrate.

One example of an application of the substrate-treating method of this embodiment will described in detail with reference to drawings. Each step will be described below.

Applying Step

In this step, the composition for forming a substrate treatment film is applied on a substrate. As the composition for forming a substrate treatment film, the composition for forming a substrate treatment film of the embodiment of the present invention described above is used. A substrate treatment film is formed on the substrate by this step.

The substrate may be either a pattern-unformed substrate or a pattern-formed substrate.

Examples of the pattern-unformed substrate include: metal or metalloid substrates such as a silicon substrate, an aluminum substrate, a nickel substrate, a chromium substrate, a molybdenum substrate, a tungsten substrate, a copper substrate, a tantalum substrate and a titanium substrate; ceramic substrates such as a silicon nitride substrate, an alumina substrate, a silicon dioxide substrate, a tantalum nitride substrate and a titanium nitride substrate; and the like. Of these, the silicon substrate, the silicon nitride substrate, or the titanium nitride substrate is preferred, and the silicon substrate is more preferred.

The pattern of the pattern-formed substrate is exemplified by: a line-and-space pattern or a trench pattern, with line widths of space portions being no greater than 2,000 nm, no greater than 1,000 nm, no greater than 500 nm, or no greater than 50 nm; a hole pattern, with diameters of holes being no greater than 300 nm, no greater than 150 nm, no greater than 100 nm, or no greater than 50 nm; and the like.

With respect to the dimensions of the pattern formed on the substrate, an exemplary fine pattern may have: a height of no less than 100 nm, no less than 200 nm, or no less than 300 nm; a width of no greater than 50 nm, no greater than 40 nm, or no greater than 30 nm; and an aspect ratio (pattern height/pattern width) of no less than 3, no less than 5, or no less than 10.

It is to be noted that in the case in which the pattern-formed substrate is used as the substrate, a coating film (hereinafter, may be also referred to as “coating film (a)”) formed by applying the composition for forming a substrate treatment film on the substrate preferably enables recessed portions of the pattern to be filled therewith. Due to the coating film (a) enabling the recessed portions of the pattern to be filled therewith, particles attached to the recessed portions of the pattern can be more efficiently removed, thereby leading to a further superior particle-removing effect being achieved.

As a procedure for applying the composition for forming a substrate treatment film on the substrate, for example, a spin-coating method, a flow casting method, a roll coating method, and the like may be exemplified. Accordingly, the coating film (a) of the composition for forming a substrate treatment film is formed.

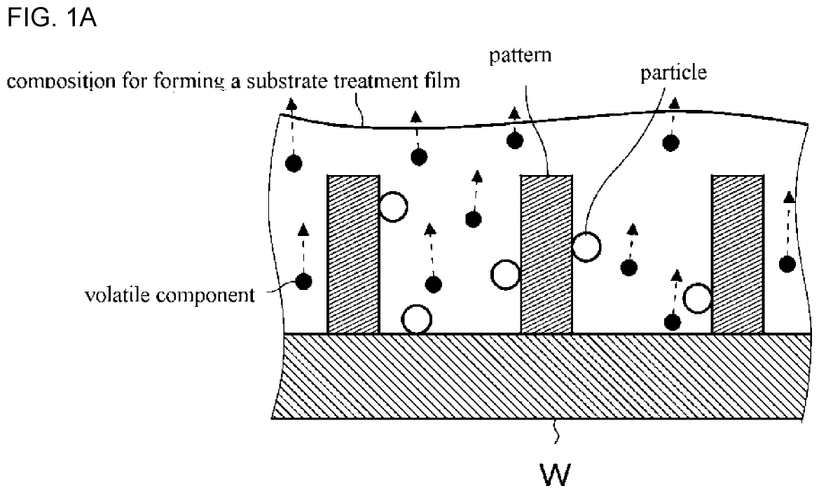

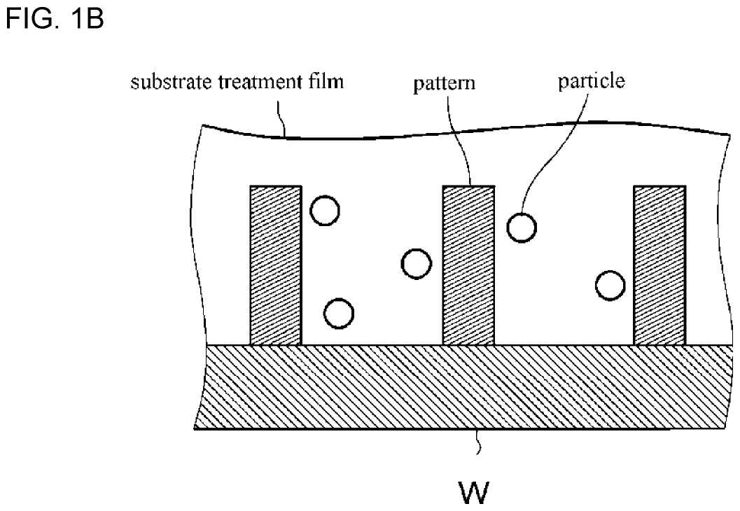

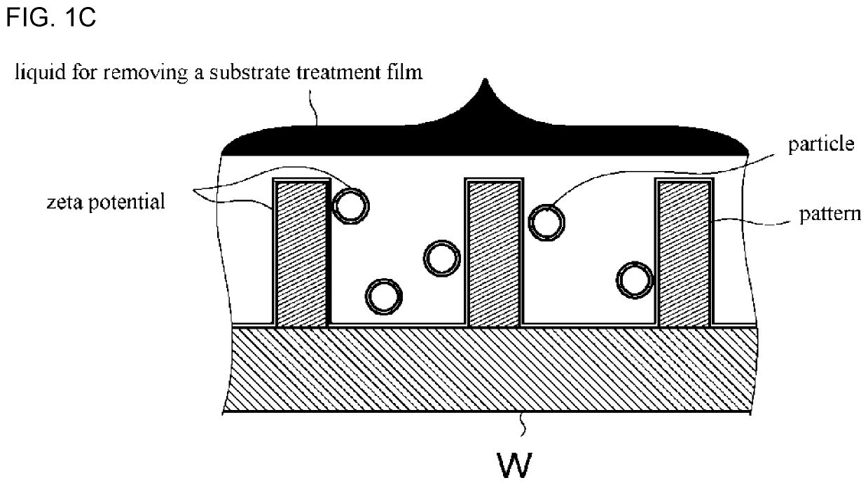

As shown in FIG. 1A, the composition for forming a substrate treatment film is first applied on a wafer W, whereby the coating film (a) of the composition for forming a substrate treatment film is formed.

Next, as shown in FIG. 1B, by evaporating a part or all of volatile components such as the solvent (B) from the coating film (a) thus formed to permit solidification or hardening of the composition for forming a substrate treatment film on the substrate, the substrate treatment film (b) is formed. The term “solidification” as referred to herein means turning into a solid state, and “hardening” as referred to means an increase of the molecular weight through linking between the molecules (for example, crosslinking, polymerization and the like). In this procedure, the particles attached to the pattern, the wafer W and the like are incorporated into the substrate treatment film (b) and drawn away from the pattern, the wafer W and the like.

In this case, the solidification or hardening of the coating film (a) can be promoted by subjecting the coating film (a) to heat and/or reduced pressure.

The lower limit of a temperature of the heating for the solidification and/or hardening is preferably 30° C., and more preferably 40° C. The upper limit of the temperature of the heating is preferably 200° C., more preferably 100° C., and still more preferably 90° C. The lower limit of a time period of the heating is preferably 5 sec, more preferably 10 sec, and still more preferably 30 sec. The upper limit of the time period of the heating is preferably 10 min, more preferably 5 min, and still more preferably 2 min.

The lower limit of an average thickness of the substrate treatment film (b) formed is preferably 10 nm, more preferably 20 nm, and still more preferably 50 nm. The upper limit of the average thickness is preferably 1,000 nm, and more preferably 500 nm.

The lower limit of a proportion of the solvent (B) contained in the substrate treatment film (b) formed is preferably 0.01% by mass, more preferably 0.1% by mass, still more preferably 1% by mass, and particularly preferably 2% by mass. The upper limit of the proportion is preferably 65% by mass, more preferably 50% by mass, still more preferably 30% by mass, and particularly preferably 10% by mass.

Step for Contacting Liquid for Removing Substrate Treatment Film

In this step, a liquid for removing a substrate treatment film, which detaches the substrate treatment film (B) from the substrate, is brought into contact with the substrate treatment film (B) provided by solidification or hardening of the composition for forming a substrate treatment film on the substrate through evaporation of the volatile components.

As shown in FIG. 1C, the liquid for removing a substrate treatment film is brought into contact with the substrate treatment film (b) to thus remove the substrate treatment film (b) entirely from the wafer W. As a result, the particles are removed from the wafer W together with the substrate treatment film (b).

As the liquid for removing a substrate treatment film, water, an organic solvent, an alkaline aqueous solution or the like may be used. The liquid for removing a substrate treatment film is preferably a liquid containing water, more preferably water or the alkaline aqueous solution, and still more preferably the alkaline aqueous solution. As the aqueous alkaline solution, an alkaline developer solution may be used, which may be a well-known alkaline developer solution. Specific examples of the alkaline developer solution include aqueous solutions containing at least one of ammonia, tetramethylammonium hydroxide (TMAH) and choline, and the like. As the organic solvent, for example, a thinner, isopropyl alcohol (IPA), 4-methyl-2-pentanol (MIBC), toluene, acetic acid esters, alcohols, glycols (propylene glycol monomethyl ether, etc.) or the like may be used. Also, the removal of the substrate treatment film (b) may be carried out sequentially by using different types of the liquid for removing a substrate treatment film, e.g., by bringing water as the liquid for removing a substrate treatment film first into contact with the substrate treatment film (b), and then bringing an alkaline developer solution into contact therewith. By sequentially using different types of the liquid for removing a substrate treatment film, film removability can be further improved.

When the liquid for removing a substrate treatment film such as an alkaline developer solution or the like is brought into contact, zeta potentials having identical polarity (in this case, negative) are generated on the wafer W, the pattern surface and the particle surface, as shown in FIG. 1C. The particles drawn away from the wafer W and the like are charged with a zeta potential having identical polarity to that of the wafer W and the like, leading to mutual repulsion with respect to the wafer W and the like. Accordingly, reattachment of the particle to the wafer W and the like can be further inhibited.

In this manner, according to the substrate-treating method of the embodiment of the present invention, the particles can be removed with a weaker force as compared with conventional removal of the particles by way of physical force, and therefore, pattern collapse can be inhibited. In addition, since the particles are removed without utilizing a chemical action, erosion of the wafer W and pattern due to an etching action, etc., can be also inhibited. Furthermore, smaller particles, and particles embedded into gaps of the pattern can be also easily removed, for which the removal is difficult according to a cleaning method for substrates carried out using a physical force.

The composition for forming a substrate treatment film brought into contact with the wafer W is finally removed completely from the wafer W. Therefore, the wafer W after the cleaning will have a state as before being brought into contact with the composition for forming a substrate treatment film, more specifically, a state with a circuit-provided face being exposed.

The substrate-treating method may be carried out using at least one of various well-known apparatuses, memory mediums and the like. A suitable apparatus is exemplified by an apparatus for cleaning a substrate disclosed in Japanese Unexamined Patent Application, Publication No. 2014-99583. A specific exemplary apparatus may include a cleaning apparatus for a semiconductor substrate, including: a first liquid-feeding zone for supplying the composition for forming a substrate treatment film to a semiconductor substrate; and a second liquid-feeding zone for supplying on the film, a removing liquid for dissolving the film formed from the composition for forming a substrate treatment film supplied to the substrate by the aforementioned first liquid-feeding zone. Furthermore, an exemplary memory medium may include a computer-readable memory medium that stores a program for controlling the apparatus for cleaning a substrate and is capable of operating on a computer, wherein the program allows the computer to control the apparatus for cleaning a substrate such that the substrate-treating method of the substrate is carried out upon execution.

### EXAMPLES

Hereinafter, the embodiment of the present invention will be explained in more detail by way of Examples, but the present invention is not in any way limited to these Examples. Each physical property in the Examples was determined in accordance with the following method.

Weight Average Molecular Weight (Mw)

The Mw of the resin was determined by gel permeation chromatography (detector: differential refractometer) using GPC columns (“G2000HXL”×2, “G3000HXL”×1, “G4000HXL”×1, available from Tosoh Corporation) under analytical conditions involving a flow rate of 1.0 mL/min, an elution solvent of tetrahydrofuran and a column temperature of 40° C., with mono-dispersed polystyrene as a standard.

Average Thickness of Film

The average thickness of the film was measured by using a spectroscopic ellipsometer (“M2000D,” available from J.A. Woollam Co.).

### Synthesis of Resin (A)

Resins represented by the following formulae (A-1) to (A-4) (hereinafter, also referred to as “resins (A-1) to (A-4)”) were synthesized according to the procedure shown below.

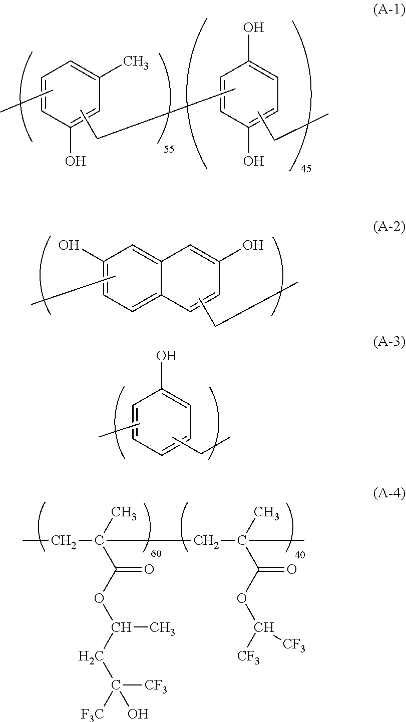

### Synthesis Example 1: Synthesis of Resin (A-1)

Into a reaction vessel, 70 g of m-cresol, 57.27 g of p-cresol, 95.52 g of 37% by mass formaldehyde and 381.82 g of methyl isobutyl ketone were charged and dissolved in a nitrogen atmosphere. After a thus obtained solution was heated to 40° C., 2.03 g of paratoluenesulfonic acid was added thereto and a reaction was allowed at 85° C. for 4 hrs. The reaction mixture was cooled to 30° C. or below, and this reaction mixture was charged into a mixed solution of methanol/water (50/50 (mass ratio)) to permit reprecipitation. The precipitate was collected on a filter paper and then dried to give the resin (A-1). The Mw of the resin (A-1) was 50,000.

### Synthesis Example 2: Synthesis of Resin (A-2)

Into a reaction vessel, 150 g of 2,7-dihydroxynaphthalene, 76.01 g of 37% by mass formaldehyde and 450 g of methyl isobutyl ketone were charged and dissolved in a nitrogen atmosphere. After a thus obtained solution was heated to 40° C., 1.61 g of paratoluenesulfonic acid was added thereto and a reaction was allowed at 80° C. for 7 hrs. The reaction mixture was cooled to 30° C. or below, and this reaction mixture was charged into a mixed solution of methanol/water (50/50 (mass ratio)) to permit reprecipitation. The precipitate was collected on a filter paper and then dried to give the resin (A-2). The Mw of the resin (A-2) was 3,000.

### Synthesis Example 3: Synthesis of Resin (A-3)

Into a reaction vessel, 120 g of phenol, 103.49 g of 37% by mass formaldehyde and 360.00 g of methyl isobutyl ketone were charged and dissolved in a nitrogen atmosphere. After a thus obtained solution was heated to 40° C., 2.20 g of paratoluenesulfonic acid was added thereto and a reaction was allowed at 79° C. for 4 hrs. The reaction mixture was cooled to 30° C. or below, and this reaction mixture was charged into a mixed solution of methanol/water (50/50 (mass ratio)) to permit reprecipitation. The precipitate was collected on a filter paper and then dried to give the resin (A-3). The Mw of the resin (A-3) was 10,000.

### Synthesis Example 4: Synthesis of Resin (A-4)

A monomer solution was prepared by dissolving 64.49 g of a compound (M-1) represented by the following formula (M-1), 34.51 g of a compound (M-2) represented by the following formula (M-2) and 4.20 g of azobisisobutyronitrile (AIBN) in 100 g of 2-butanone. A 1,000-mL three-neck flask which had been charged with 100 g of 2-butanone was purged with nitrogen for 30 min. The nitrogen purge was followed by heating to 80° C., and the monomer solution prepared as described above was added dropwise with stirring over 3 hrs. The time of the start of the dropwise addition was regarded as the time of the start of the polymerization reaction, and the polymerization was allowed for 6 hrs. After completing the polymerization, the reaction solution was cooled to no higher than 30° C. The reaction solution was concentrated under reduced pressure to give a mass of 150 g. To a resultant concentrate were charged 150 g of methanol and 750 g of n-hexane, and the mixture was separated into an upper layer liquid and an underlayer liquid. After such separation, the underlayer liquid was recovered. To the recovered underlayer liquid was charged 750 g of n-hexane, and again separation was allowed to recover the underlayer liquid. The solvent was removed from the underlayer liquid thus recovered, and 4-methyl-2-pentanol was added thereto to give a solution containing the resin (A-4). The Mw of the resin (A-4) was 10,000.

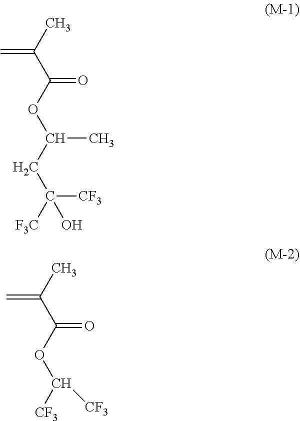

### Preparation of Composition for Forming Substrate Treatment Film

Each component used in preparing the composition for forming a substrate treatment film is as presented below.

(A) Resin

The resins (A-1) to (A-4) synthesized by the above Synthesis Examples were used.

(B) Solvent

(B1) Solvent component

B1-1: tetraethylene glycol (boiling point: 314° C.)

B1-2: triethylene glycol (boiling point: 287° C.)

B1-3: propylene glycol (boiling point: 187° C.)

B1-4: dipropylene glycol (boiling point: 231° C.)

B1-5: diethylene glycol monoethyl ether (boiling point: 196° C.)

B1-6: tripropylene glycol (boiling point: 267° C.)

B1-7: diethylene glycol methyl ethyl ether (boiling point: 176° C.)

B1-8: 1,2-hexanediol (boiling point: 223° C.)

(B2) Solvent component

B2-1: propylene glycol monomethyl ether acetate (boiling point: 146° C.)

B2-2: ethyl lactate (boiling point: 151° C.)

B2-3: propylene glycol monomethyl ether (boiling point: 121° C.)

B2-4: propylene glycol monoethyl ether (boiling point: 133° C.)

B2-5: 4-methyl-2-pentanol (boiling point: 132° C.)

(C) Organic acid

C-1: malic acid

C-2: acetic acid

### Example 1

Five parts by mass of (A-1) as the resin (A), and 0.15 parts by mass of (C-1) as the organic acid (C) were dissolved in the solvent (B) including 1 part by mass of (B1-1) as the solvent component (B1), and 99 parts by mass of (B2-4) as the solvent component (B2). A resultant solution was filtered through a membrane filter having a pore size of 0.1 μm to prepare a composition for forming a substrate treatment film (J-1).

Examples 2 to 25 and Comparative Examples 1 to 5 Each of compositions (J-2) to (J-30) for forming a substrate treatment film was prepared in a similar manner to Example 1 except that each component of the type and in the content shown in Table 1 below was used. In Table 1, a denotation “-” indicates that a corresponding component was not used.

TABLE 1

| | | | | (B) Solvent | | | | | |
|---|---|---|---|---|---|---|---|---|---|
| | Composition | | | (B1) Solvent | | (B2) Solvent | | | |
| | for forming | (A) Resin | | component | | component | | (C) Organic acid | |
| | substrate | | content | | content | | content | | content |
| | treatment | | (parts by | | (parts by | | (parts by | | (parts by |
| | film | type | mass) | type | mass) | type | mass) | type | mass) |
| Example 1 | J-1 | A-1 | 5 | B1-1 | 1 | B2-4 | 99 | C-1 | 0.15 |
| Example 2 | J-2 | A-1 | 5 | B1-2 | 1 | B2-4 | 99 | C-1 | 0.15 |
| Example 3 | J-3 | A-1 | 5 | B1-3 | 1 | B2-4 | 99 | C-1 | 0.15 |
| Example 4 | J-4 | A-1 | 5 | B1-4 | 1 | B2-4 | 99 | C-1 | 0.15 |
| Example 5 | J-5 | A-1 | 5 | B1-5 | 1 | B2-4 | 99 | C-1 | 0.15 |
| Example 6 | J-6 | A-1 | 5 | B1-6 | 1 | B2-4 | 99 | C-1 | 0.15 |
| Example 7 | J-7 | A-1 | 5 | B1-7 | 1 | B2-4 | 99 | C-1 | 0.15 |
| Example 8 | J-8 | A-1 | 5 | B1-2 | 1 | B2-4 | 99 | — | — |
| Example 9 | J-9 | A-1 | 5 | B1-1 | 5 | B2-4 | 95 | C-1 | 0.15 |
| Example 10 | J-10 | A-1 | 5 | B1-2 | 5 | B2-4 | 95 | C-1 | 0.15 |
| Example 11 | J-11 | A-1 | 5 | B1-3 | 5 | B2-4 | 95 | C-1 | 0.15 |
| Example 12 | J-12 | A-1 | 5 | B1-4 | 5 | B2-4 | 95 | C-1 | 0.15 |
| Example 13 | J-13 | A-1 | 5 | B1-5 | 5 | B2-4 | 95 | C-1 | 0.15 |
| Example 14 | J-14 | A-1 | 5 | B1-6 | 5 | B2-4 | 95 | C-1 | 0.15 |
| Example 15 | J-15 | A-1 | 5 | B1-7 | 5 | B2-4 | 95 | C-1 | 0.15 |
| Example 16 | J-16 | A-2 | 5 | B1-2 | 5 | B2-4 | 95 | C-1 | 0.15 |
| Example 17 | J-17 | A-3 | 5 | B1-2 | 5 | B2-4 | 95 | C-1 | 0.15 |
| Example 18 | J-18 | A-4 | 5 | B1-2 | 5 | B2-4 | 95 | C-1 | 0.15 |
| Example 19 | J-19 | A-1 | 5 | B1-3 | 10 | B2-4 | 90 | C-1 | 0.15 |
| Example 20 | J-20 | A-1 | 5 | B1-4 | 10 | B2-4 | 90 | C-1 | 0.15 |
| Example 21 | J-21 | A-1 | 5 | B1-5 | 10 | B2-4 | 90 | C-1 | 0.15 |
| Example 22 | J-22 | A-1 | 5 | B1-2 | 5 | B2-1 | 95 | C-1 | 0.15 |
| Example 23 | J-23 | A-1 | 5 | B1-2 | 5 | B2-2 | 95 | C-2 | 0.15 |
| Example 24 | J-24 | A-1 | 5 | B1-2 | 5 | B2-3 | 95 | C-1 | 0.15 |
| Example 25 | J-25 | A-1 | 5 | B1-2 | 5 | B2-5 | 95 | C-1 | 0.15 |
| Comparative | J-26 | A-1 | 5 | — | — | B2-2 | 100 | C-1 | 0.15 |
| Example 1 | | | | | | | | | |
| Comparative | J-27 | A-1 | 5 | — | — | B2-3 | 100 | C-1 | 0.15 |
| Example 2 | | | | | | | | | |
| Comparative | J-28 | A-1 | 5 | — | — | B2-4 | 100 | C-1 | 0.15 |
| Example 3 | | | | | | | | | |
| Comparative | J-29 | A-4 | 5 | — | — | B2-4 | 100 | C-1 | 0.15 |
| Example 4 | | | | | | | | | |
| Comparative | J-30 | A-4 | 5 | — | — | B2-5 | 100 | — | — |
| Example 5 | | | | | | | | | |

### Cleaning of Semiconductor Substrate

Cleaning of a semiconductor substrate was carried out in accordance with the following method using each composition for forming a substrate treatment film of Examples 1 to 25 and Comparative Examples 1 to 5.

Silica particles having a particle diameter of 80 nm were attached onto an 8-inch silicon wafer having a line-and-space pattern (1L 1S, aspect ratio: 1) formed thereon with the line widths of space portions being 1,000 nm. Each composition for forming a substrate treatment film was applied on the silicon wafer to give a substrate provided with the substrate treatment film by a spin-coating method under a condition involving 1,500 rpm for 30 sec. After three hours had passed from immediately after formation of the substrate treatment film, by using a puddle development apparatus, a liquid film of a 2.38% by mass aqueous tetramethylammonium hydroxide solution as a liquid for removing a substrate treatment film was formed on the substrate treatment film, whereby immersion into the liquid for removing the substrate treatment film was started. After thirty minutes had passed from the start of the immersion, cleaning of the semiconductor substrate was completed through washing with water and drying by a spin-drying method.

### Evaluations

With respect to the semiconductor substrate cleaned as described above, the entire surface of the semiconductor substrate was analyzed by using a defect inspection system in the dark field (“KLA2800”, available from KLA-TENCOR Corporation) to evaluate the film removability and the particle removability. The results of the evaluations are shown together in Table 2 below.

The film removability was evaluated, on the basis of the number of residual defects other than silica particles, to be: “A” (extremely favorable) in a case of the number being less than 10 defects/cm²; “B” (favorable) in a case of the number being no less than 10 defects/cm′ and less than 50 defects/cm²; and “C” (unfavorable) in a case of the number being no less than 50 defects/cm′. The particle removability was evaluated, on the basis of the rate of removal of the silica particles, to be: “A” (extremely favorable) in a case of the rate being no less than 90%; “B” (favorable) in a case of the rate being no less than 50% and less than 90%; and “C” (unfavorable) in a case of the rate being less than 50%.

TABLE 2

| | Composition for forming | Film | Particle |
|---|---|---|---|
| | substrate treatment film | removability | removability |
| Example 1 | J-1 | A | A |
| Example 2 | J-2 | A | A |
| Example 3 | J-3 | B | B |
| Example 4 | J-4 | A | A |
| Example 5 | J-5 | B | B |
| Example 6 | J-6 | A | A |
| Example 7 | J-7 | B | B |
| Example 8 | J-8 | A | B |
| Example 9 | J-9 | A | A |
| Example 10 | J-10 | A | A |
| Example 11 | J-11 | A | A |
| Example 12 | J-12 | A | A |
| Example 13 | J-13 | A | A |
| Example 14 | J-14 | A | A |
| Example 15 | J-15 | A | A |
| Example 16 | J-16 | A | A |
| Example 17 | J-17 | A | A |
| Example 18 | J-18 | A | A |
| Example 19 | J-19 | A | A |
| Example 20 | J-20 | A | A |
| Example 21 | J-21 | A | A |
| Example 22 | J-22 | A | A |
| Example 23 | J-23 | A | A |
| Example 24 | J-24 | A | A |
| Example 25 | J-25 | A | A |
| Comparative | J-26 | C | C |
| Example 1 | | | |
| Comparative | J-27 | C | C |
| Example 2 | | | |
| Comparative | J-28 | C | C |
| Example 3 | | | |
| Comparative | J-29 | C | C |
| Example 4 | | | |
| Comparative | J-30 | C | C |
| Example 5 | | | |

As shown in Table 2, each composition for forming a substrate treatment film of the Examples was favorable or extremely favorable in terms of both the film removability and the particle removability. On the other hand, each composition for forming a substrate treatment film of the Comparative Examples was unfavorable in terms of both the film removability and particle removability.

The composition for forming a substrate treatment film and the substrate-treating method of the embodiments of the present invention enable, in a process for forming a substrate treatment film on a surface of a semiconductor substrate and removing unwanted substances on the surface of the substrate, fine particles on the surface of the substrate to be efficiently removed, and also enable easy removal of a thus formed substrate treatment film from the surface of the substrate. Therefore, the embodiments of the present invention can be suitably used in manufacturing processes of semiconductor elements for which further progress of miniaturization, and an increase of the aspect ratio are expected in the future.

Obviously, numerous modifications and variations of the present invention are possible in light of the above teachings. It is therefore to be understood that within the scope of the appended claims, the invention may be practiced otherwise than as specifically described herein.

What is claimed is:

1. A composition which enables particles to be removed from a surface of a substrate by:
applying the composition on the surface of the substrate to form a substrate treatment film on the surface; and
bringing a liquid into contact with the substrate treatment film to remove the substrate treatment film from the surface,
wherein the composition comprises:
a resin; and
a solvent,
wherein the solvent comprises a first solvent component having a normal boiling point of no less than 175° C., and
a content of the first solvent component with respect to 100 parts by mass of the resin is no less than 1 part by mass.

2. The composition according to claim 1, wherein the first solvent component comprises a hydroxy group.

3. The composition according to claim 2, wherein the first solvent component comprises the hydroxy groups in a plurality.

4. The composition according to claim 1, wherein C log P of the first solvent component is no greater than 0.6.

5. The composition according to claim 1, wherein the first solvent component comprises an ether bond.

6. The composition according to claim 1, wherein the first solvent component has a normal boiling point of no less than 230° C.

7. The composition according to claim 1, wherein the solvent further comprises a second solvent component having a normal boiling point of no greater than 170° C.

8. The composition according to claim 1, further comprising an organic acid not being a polymer.

9. The composition according to claim 1, wherein the liquid comprises water.

10. A substrate-treating method comprising:
applying a composition on a surface of a substrate to form a substrate treatment film on the surface; and
bringing a liquid into contact with a substrate treatment film to remove a substrate treatment film from the surface,
wherein the composition comprises:
a resin; and
a solvent,
wherein the solvent comprises a first solvent component having a normal boiling point of no less than 175° C., and
a content of the first solvent component with respect to 100 parts by mass of the resin is no less than 1 part by mass.

11. The substrate-treating method according to claim 10, wherein the first solvent component comprises a hydroxy group.

12. The substrate-treating method according to claim 11, wherein the first solvent component comprises the hydroxy groups in a plurality.

13. The substrate-treating method according to claim 10, wherein C log P of the first solvent component is no greater than 0.6.

14. The substrate-treating method according to claim 10, wherein the first solvent component comprises an ether bond.

15. The substrate-treating method according to claim 10, wherein the first solvent component has a normal boiling point of no less than 230° C.

16. The substrate-treating method according to claim 10, wherein the solvent further comprises a second solvent component having a normal boiling point of no greater than 170° C.

17. The substrate-treating method according to claim 10, wherein the composition further comprises an organic acid not being a polymer.

18. The substrate-treating method according to claim 10, wherein the liquid comprises water.

19. The substrate-treating method according to claim 16, wherein the first solvent component comprises at least one selected from the group consisting of tetraethylene glycol, diethylene glycol monoethyl ether, diethylene glycol methyl ethyl ether, and 1,2-hexanediol.

20. The substrate-treating method according to claim 16, wherein the content of the first solvent component with respect to 100 parts by mass of the resin is no less than 50 parts by mass and no greater than 1,000 parts by mass.
